(19) United States
(12) Patent Application Publication
(10) Pub. No.: US 2025/0255076 A1
(43) Pub. Date: Aug. 7, 2025

(54) DISPLAY DEVICE

(71) Applicant: Samsung Display Co., LTD., Yongin-si (KR)

(72) Inventors: Woo Lim JEONG, Yongin-si (KR); Young Chul SIM, Yongin-si (KR); Seung A LEE, Yongin-si (KR)

(21) Appl. No.: 18/969,006

(22) Filed: Dec. 4, 2024

(30) Foreign Application Priority Data
Feb. 6, 2024 (KR) 10-2024-0018459

(51) Int. Cl. H10H 29/80; H10H 29/24; H10H 29/49; H10H 29/85

(52) U.S. Cl. CPC H10H 29/8421; H10H 29/24; H10H 29/49; H10H 29/8517

(57) ABSTRACT

A display device comprises: a pixel circuit layer, a bonding electrode on the pixel circuit layer, a first electrode on the bonding electrode, a light-emitting element on the first electrode and configured to emit light of a first color, a second electrode on the light-emitting element, a distributed Bragg reflective layer on the second electrode, and a color filter on the distributed Bragg reflective layer and transmitting light of a second color.

### CROSS-REFERENCE TO RELATED APPLICATION

The present application claims priority to, and the benefit of, Korean Patent Application No. 10-2024-0018459, filed on Feb. 6, 2024, in the Korean Intellectual Property, the entire disclosure of which is incorporated herein by reference.

### BACKGROUND

### 1. Field

Aspects of some embodiments of the present disclosure relate to a display device.

### 2. Description of the Related Art

As information technology is developed, an importance of a display device, which is a connection medium between users and information, has been highlighted. Therefore, a display device, such as a liquid crystal display device, an organic light-emitting diode display device, and the like, has been increasingly used.

The above information disclosed in this Background section is only for enhancement of understanding of the background, and therefore the information discussed in this Background section does not necessarily constitute prior art.

### SUMMARY

Aspects of some embodiments of the present disclosure include a display device with increased light efficiency and color purity.

According to some embodiments of the present disclosure, a display device includes a pixel circuit layer, a bonding electrode above the pixel circuit layer, a first electrode above the bonding electrode, a light-emitting element above the first electrode for emitting light of a first color, a second electrode above the light-emitting element, a distributed Bragg reflective layer above the second electrode, and a color filter above the distributed Bragg reflective layer for transmitting light of a second color.

The first color may be orange.

The second color may be red.

The color filter may be configured to absorb or reflect light of a color other than red.

The display device may further include a lens between the distributed Bragg reflective layer and the color filter.

The display device may further include a first protective layer on the first electrode, on a side surface of the light-emitting element, and on the second electrode, a second protective layer on the pixel circuit layer, on the bonding electrode, on the first electrode, and on the first protective layer, and a reflective layer on a side surface of the second protective layer and on the pixel circuit layer.

The reflective layer might not overlap the light-emitting element.

The display device may further include a first insulating layer between the pixel circuit layer and the second electrode, and covering the reflective layer and the second protective layer, and a second insulating layer on the second electrode and the distributed Bragg reflective layer.

The distributed Bragg reflective layer may include at least one multilayer in which a first refractive layer, a second refractive layer, and another first refractive layer are sequentially stacked.

The first refractive layers may include titanium dioxide, wherein the second refractive layer includes silicon dioxide, and wherein a thickness of the multilayer is about 130 nm to about 160 nm.

The first refractive layers may include tantalum dioxide, wherein the second refractive layer includes silicon dioxide, and wherein a thickness of the multilayer is about 150 nm to about 180 nm.

The multilayer may include 3 to 60 layers.

The display device may further include a first protective layer on the first electrode, on a side surface of the light-emitting element, and on a side surface of the second electrode, a second protective layer on a side surface of the first protective layer, on the pixel circuit layer, on the bonding electrode, and on the first electrode, and a reflective layer on a side surface of the distributed Bragg reflective layer, on the pixel circuit layer, on the first protective layer, on the second protective layer, and on the second electrode.

The reflective layer may partially overlap the light-emitting element.

The display device may further include a first insulating layer between the reflective layer and the pixel circuit layer, and a second insulating layer between the color filter and the distributed Bragg reflective layer and the reflective layer.

According to some embodiments of the present disclosure, a display device includes a first light-emitting element at a same layer as a first insulating layer above a pixel circuit layer, and configured to emit light of a first color, a distributed Bragg reflective layer above the first insulating layer, a color filter above the distributed Bragg reflective layer, and configured to transmit red color light, a second light-emitting element at same layer as a second insulating layer above the color filter, and configured to emit light of a second color, and a third light-emitting element at same layer as a third insulating layer above the second insulating layer, and configured to emit light of a third color.

The first color may be orange, wherein the second color is green, and wherein the third color is blue.

The display device may further include first electrodes above the pixel circuit layer, first vias penetrating the first insulating layer, the distributed Bragg reflective layer, and the color filter, second vias penetrating the second insulating layer, third vias penetrating the third insulating layer, a second electrode above the third insulating layer, and lenses above the second electrode, and respectively overlapping the first light-emitting element, the second light-emitting element, and the third light-emitting element.

The first light-emitting element may be above one of the first electrodes overlapping a first light-emitting area, and may be electrically connected to the second electrode through one of the first vias overlapping the first light-emitting area, one of the second vias overlapping the first light-emitting area, and one of the third vias overlapping the first light-emitting area.

The second light-emitting element may be electrically connected to one of the first electrodes overlapping a second light-emitting area through one of the first vias overlapping the second light-emitting area, and may be electrically connected to the second electrode through one of the second vias overlapping the second light-emitting area and one of the third vias overlapping the second light-emitting area.

The third light-emitting element may be electrically connected to one of the first electrodes overlapping a third light-emitting area through one of the first vias overlapping the third light-emitting area and one of the second vias overlapping the third light-emitting area, and may be electrically connected to the second electrode through one of the third vias overlapping the third light-emitting area.

### BRIEF DESCRIPTION OF THE DRAWINGS

The above and other aspects of embodiments according to the present disclosure will become more apparent by describing, in further detail, aspects of some embodiments thereof with reference to the accompanying drawings, in which:

FIG. 1 is a block diagram of a display device according to some embodiments.

FIG. 2 is a block diagram of a sub-pixel according to some embodiments.

FIG. 3 is a plan view of a display panel according to some embodiments.

FIG. 4 is a plan view of a pixel according to some embodiments.

FIG. 5 is a cross-sectional view taken along the line I-I′ of FIG. 4 according to some embodiments.

FIG. 6 is a cross-sectional view of a distributed Bragg reflective layer according to some embodiments.

FIG. 7 is a cross-sectional view taken along the line I-I′ of FIG. 4 according to some embodiments.

FIG. 8 is a cross-sectional view taken along the line II-II′ of FIG. 4 according to some embodiments.

FIG. 9 is a block diagram of a display system according to some embodiments.

FIGS. 10 to 13 are perspective views of application examples of a display system of FIG. 9.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present. For the purposes of this disclosure, expressions such as “at least one of,” or

“any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively. In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

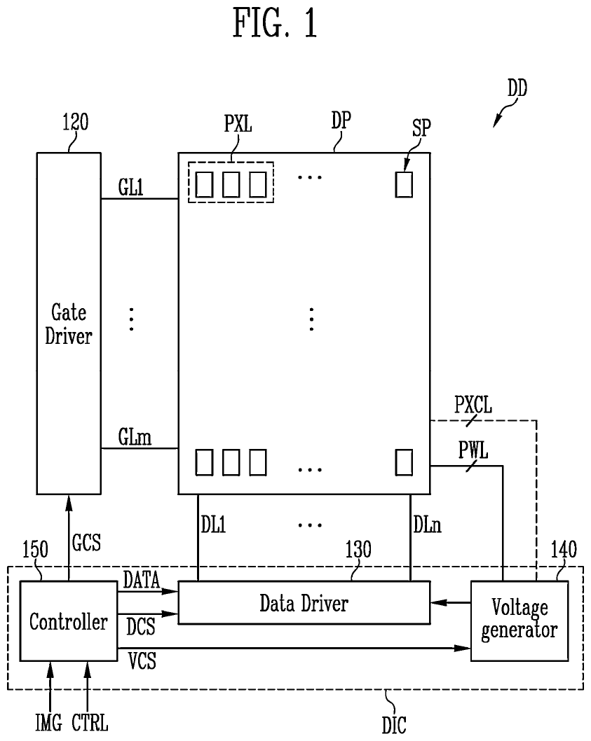

FIG. 1 is a block diagram of a display device according to some embodiments.

Referring to FIG. 1, the display device 100 may include a display panel DP, a gate driver 120, a data driver 130, a voltage generator 140, and a controller 150.

The display panel DP includes sub-pixels SP. The sub-pixels SP may be connected to the gate driver 120 through the first to m-th gate lines GL1 to GLm. The sub-pixels SP may be connected to the data driver 130 through the first to n-th data lines DL1 to DLn.

The sub-pixels SP may generate light of two or more colors. For example, each of the sub-pixels SP may generate light, such as red, green, blue, cyan, magenta, yellow, etc.

Two or more sub-pixels among the sub-pixels (SP) may constitute one pixel PXL. For example, the pixel PXL may include three sub-pixels as shown in FIG. 1. In this way, the pixel PXL may emit light of various colors and various brightnesses depending on the combination of light emitted from the sub-pixels included in the pixel.

The gate driver 120 may be connected to the sub-pixels SP arranged in the row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, etc.

The gate driver 120 may be located on one side of the display panel DP. However, the embodiments are not limited thereto. For example, the gate driver 120 may be divided into two or more drivers separated physically and/or logically, and such drivers may be respectively located on one side of the display panel DP, and on the other side of the display panel DP opposite the one side. As such, the gate driver 120 may be located around the display panel DP in various shapes according to the embodiments.

The data driver 130 may be connected to the sub-pixels SP arranged in a column direction through the first to n-th data lines DL1 to DLn. The data driver 130 may receive image data DATA and data control signal DCS from the controller 150. The data driver 130 may operate in response to the data control signal DCS. In embodiments, the data control signal DCS may include a source start signal, a source shift clock, a source output enable signal, etc.

The data driver 130 may receive voltages from the voltage generator 140. The data driver 130 may apply data signals having grayscale voltages corresponding to the image data DATA to the first to n-th data lines DL1 to DLn using the received voltages. When a gate signal is applied to each of the first to m-th gate lines GL1 to GLm, data signals corresponding to the image data DATA may be applied to the first to n-th data lines DL1 to DLn. Accordingly, the sub-pixels SP may generate light corresponding to data signals, and the display panel DP may display an image.

In embodiments, the gate driver 120 and data driver 130 may include complementary metal-oxide semiconductor (CMOS) circuit elements.

The voltage generator 140 may operate in response to a voltage control signal VCS from controller 150. The voltage generator 140 may be configured to generate a plurality of voltages and provide the generated voltages to components of the display device 100, such as the gate driver 120, the data driver 130, and the controller 150. The voltage generator 140 may generate a plurality of voltages by receiving an input voltage from outside the display device 100 and regulating the received voltage.

The voltage generator 140 may generate a first power voltage and a second power voltage. The generated first and second power voltages may be provided to the sub-pixels SP through the power lines PL. In other embodiments, at least one of the first or second power voltages may be provided from outside the display device 100.

In addition, the voltage generator 140 may provide various voltages and/or signals. For example, the voltage generator 140 may provide one or more initialization voltages applied to the sub-pixels SP. For example, during a sensing operation to sense electrical characteristics of the transistors and/or light-emitting elements of the sub-pixels SP, a reference voltage (e.g., predetermined reference voltage) may be applied to the first to n-th data lines DL1 to DLn, and the voltage generator 140 may generate the reference voltage, and may transmit the reference voltage to the data driver 130. For example, during a display operation to display an image on the display panel DP, common pixel control signals may be applied to the sub-pixels SP, and the voltage generator 140 may generate the pixel control signals. In embodiments, the voltage generator 140 may provide pixel control signals to the sub-pixels SP through the pixel control lines PXCL. In FIG. 1, the pixel control lines PXCL are shown as connected between the voltage generator 140 and the display panel DP, but the embodiments are not limited thereto. For example, the pixel control lines PXCL may be connected between the gate driver 120 and the display panel DP. In this case, the pixel control signals may be transmitted from the gate driver 120 to the sub-pixels SP through the pixel control lines PXCL.

The controller 150 may control various operations of the display device 100. The controller 150 may receive input image data IMG and a corresponding control signal CTRL from the outside. The controller 150 may provide a gate control signal GCS, a data control signal DCS, and a voltage control signal VCS in response to the control signal CTRL.

The controller 150 may convert the input image data IMG to suit the display device 100 or the display panel DP, and may output image data DATA. In embodiments, the controller 150 may arrange the input image data IMG to suit the sub-pixels SP in units of rows and output image data DATA.

Two or more components of the data driver 130, voltage generator 140, and controller 150 may be mounted on one integrated circuit. As shown in FIG. 1, the data driver 130, voltage generator 140, and controller 150 may be included in a driver integrated circuit DIC. In this case, the data driver 130, voltage generator 140, and controller 150 may be functionally separate components within one driver integrated circuit DIC. In other embodiments, at least one of the data driver 130, the voltage generator 140, or the controller 150 may be provided as a separate component from the driver integrated circuit DIC.

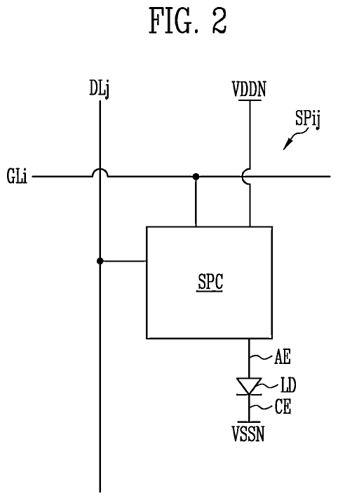

FIG. 2 is a block diagram of a sub-pixel according to some embodiments. In FIG. 2, a sub-pixel SPij arranged in the i-th row (i is an integer greater than or equal to 1 and less than or equal to m) and the j-th column (j is an integer greater than or equal to 1 and less than or equal to n) among the sub-pixels SP of FIG. 1, may be shown as an example.

Referring to FIG. 2, the sub-pixel SPij may include a sub-pixel circuit SPC and a light-emitting element LD.

The light-emitting element LD may be connected between the first power voltage node VDDN and the second power voltage node VSSN. The first power voltage node VDDN may be connected to one of the power lines PL in FIG. 1, and may receive the first power voltage. The second power voltage node VSSN may be connected to another one of the power lines PL in FIG. 1, and may receive the second power voltage. The first power voltage may have a higher voltage level than the second power voltage.

The light-emitting element LD may be connected between the anode AE and the cathode CE. The anode AE may be connected to the first power voltage node VDDN through the sub-pixel circuit SPC. For example, the anode AE may be connected to the first power voltage node VDDN through one or more transistors included in the sub-pixel circuit SPC. The cathode CE may be connected to the second power voltage node VSSN. The light-emitting element LD may be configured to emit light depending on the current flowing from the anode AE to the cathode CE.

The sub-pixel circuit SPC may be connected to the i-th gate line GLi among the first to m-th gate lines GL1 to GLm of FIG. 1, and to the j-th data line DLj among the first to n-th data lines DL1 to DLn of FIG. 1. In response to the gate signal received through the i-th gate line GLi, the sub-pixel circuit SPC may control the light-emitting element LD to emit light depending on the data signal received through the j-th data line DLj. In embodiments, the sub-pixel circuit SPC may be further connected to the pixel control lines PXCL of FIG. 1. In this case, the sub-pixel circuit SPC may control the light-emitting element LD in further response to pixel control signals received through the pixel control lines PXCL.

For these operations, the sub-pixel circuit SPC may include circuit elements, such as transistors and one or more capacitors.

The transistors of the sub-pixel circuit SPC may include P-type transistors and/or N-type transistors. In embodiments, the transistors of the sub-pixel circuit SPC may include a metal oxide silicon field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, etc.

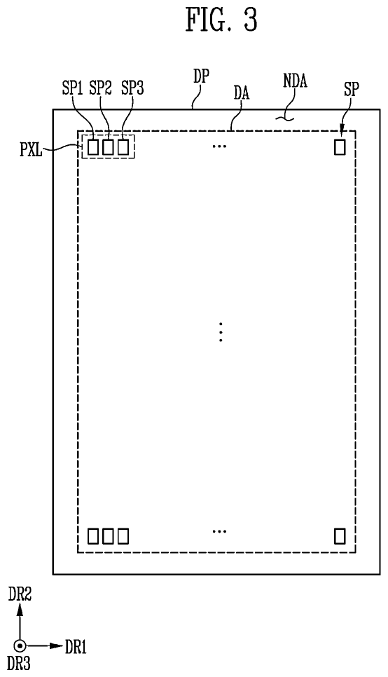

FIG. 3 is a plan view of a display panel according to some embodiments.

Referring to FIG. 3, the display panel DP may include a display area DA and a non-display area NDA. The display panel DP displays an image through the display area DA. The non-display area NDA may be located around the display area DA.

The display panel DP may include sub-pixels SP in the display area DA. The sub-pixels SP may be arranged in the first direction DR1, and in the second direction DR2 that crosses the first direction DR1. For example, the sub-pixels SP may be arranged in a matrix form in the first direction DR1 and in the second direction DR2. For another example, the sub-pixels SP may be arranged in a zigzag shape in the first direction DR1 and in the second direction DR2. The arrangement of the sub-pixels SP may vary according to embodiments. The first direction DR1 may be a row direction, and the second direction DR2 may be a column direction.

Two or more sub-pixels among the plurality of sub-pixels (SP) may constitute one pixel PXL. In FIG. 3, the pixel PXL is shown as including three sub-pixels SP1, SP2, and SP3, but the embodiments are not limited thereto. For example, the pixel PXL may include two sub-pixels. Hereinafter, for convenience of description, it is assumed that the pixel PXL includes first to third sub-pixels SP1, SP2, and SP3.

Each of the first to third sub-pixels SP1, SP2, and SP3 may generate light of one of various colors, such as red, green, blue, cyan, magenta, yellow, etc. Hereinafter, for clear and concise description, it is assumed that the first sub-pixel SP1 is configured to generate red-colored light, the second sub-pixel SP2 is configured to generate green-colored light, and the third sub-pixel SP3 is configured to generate blue-colored light.

Each of the first to third sub-pixels SP1, SP2, and SP3 may include at least one light-emitting element configured to generate light. In embodiments, the light-emitting elements of the first to third sub-pixels SP1, SP2, and SP3 may generate light of different colors. For example, the light-emitting element of the first sub-pixel SP1 may generate orange-colored light, the light-emitting element of the second sub-pixel SP2 may generate green-colored light, and the light-emitting element of the third sub-pixel SP3 may generate blue-colored light.

A display panel capable of self-luminescence, such as a light-emitting diode LED display panel that uses micro- or nano-scale light-emitting diodes as a light-emitting element, or an organic light-emitting OLED display panel that uses organic light-emitting diodes as a light-emitting element, may be used as the display panel DP.

Components for controlling the sub-pixels SP may be located in the non-display area NDA. Wires connected to the sub-pixels SP, for example, the first to m-th gate lines GL1 to GLm of FIG. 1, the first to n-th data lines DL1 to DLn, and the power lines PL, and the pixel control lines PXCL may be located in the non-display area NDA.

At least one of the gate driver 120, data driver 130, voltage generator 140, and controller 150 of FIG. 1 may be located in the non-display area NDA of the display panel DP. In embodiments, the gate driver 120 may be located in the non-display area NDA. In this case, the data driver 130, voltage generator 140, and controller 150 may be implemented as a driver integrated circuit DIC of FIG. 1 that is separated from the display panel DP, and the driver integrated circuit DIC may be connected to wires located in the non-display area NDA. In other embodiments, the gate driver 120 may be implemented as one integrated circuit separate from the display panel DP along with the data driver 130, voltage generator 140, and controller 150.

In embodiments, the display area DA may have various shapes. The display area DA may have a closed loop shape including straight and/or curved sides. For example, the display area DA may have shapes, such as a polygon, circle, semicircle, or ellipse.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate of the display panel DP may include materials having flexible properties.

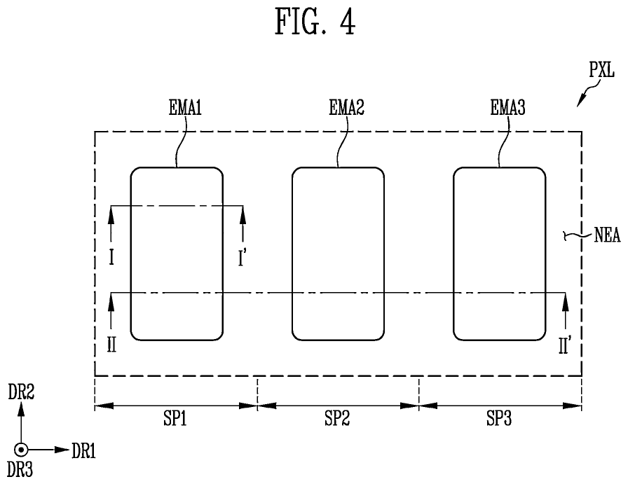

FIG. 4 is a plan view of a pixel according to some embodiments.

Referring to FIG. 4, the pixel PXL may include first to third sub-pixels SP1, SP2, and SP3 arranged in the first direction DR1. However, the arrangement of the pixels PXL is not limited thereto and may vary according to the embodiments. For example, the first to third sub-pixels SP1, SP2, and SP3 may be arranged in a zigzag pattern.

The first sub-pixel SP1 may include a first emission area EMA1, and a non-emission area NEA around the first emission area EMA1. The second sub-pixel SP2 may include a second emission area EMA2, and a non-emission area NEA around the second emission area EMA2. The third sub-pixel SP3 may include a third emission area EMA3, and a non-emission area NEA around the third emission area EMA3.

The first light-emitting area EMA1 may be an area where light is emitted from a light-emitting element corresponding to the first sub-pixel SP1. The second light-emitting area EMA2 may be an area where light is emitted from a light-emitting element corresponding to the second sub-pixel SP2. The third light-emitting area EMA3 may be an area where light is emitted from a light-emitting element corresponding to the third sub-pixel SP3.

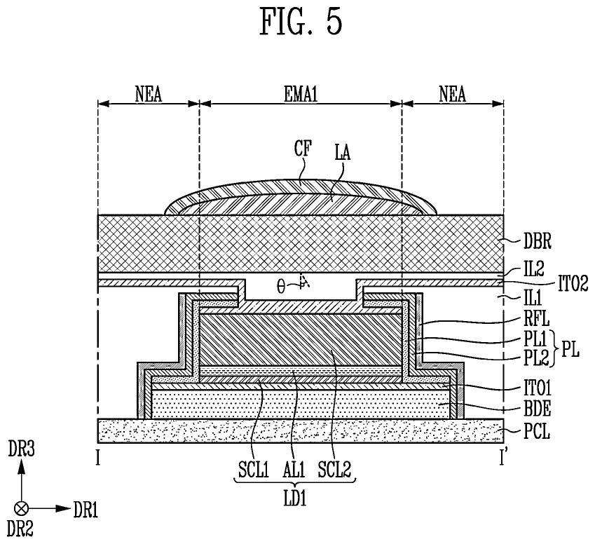

FIG. 5 is a cross-sectional view taken along the line I-I′ of FIG. 4 according to some embodiments.

Referring to FIG. 5, the pixel circuit layer PCL may be located on the substrate (as used herein, “located on” may mean “above). The substrate may be made of an insulating material, such as glass or resin. For example, the substrate may include a glass substrate. For another example, the substrate may include a polyimide (PI) substrate. For another example, the substrate may include a silicon wafer substrate formed using a semiconductor process.

In embodiments, the substrate may be made of a material that is flexible enough to bend or fold, and may have a single-layer structure or a multilayer structure. For example, the flexible material may include at least one of polystyrene, polyvinyl alcohol, polymethyl methacrylate, polyethersulfone, polyacrylate, polyether imide, polyetherimide, poly ethylene naphthalate, polyethylene terephthalate, polyphenylene sulfide, polyarylate, polyimide, polycarbonate, triacetate cellulose, or cellulose acetate propionate. However, the embodiments are not limited thereto.

The pixel circuit layer PCL may include insulating layers, semiconductor patterns, and conductive patterns. The insulating layers may include a buffer layer, one or more interlayer insulating layers, and one or more passivation layers. The semiconductor patterns and conductive patterns may be located between the insulating layers. The conductive patterns may include at least one of copper (Cu), molybdenum (Mo), tungsten (W), aluminum neodymium (AlNd), titanium (Ti), aluminum (Al), or silver (Ag).

A bonding electrode BDE may be located on the pixel circuit layer PCL. The bonding electrode BDE may include a eutectic metal. In embodiments, the bonding electrode BDE may be composed of multiple layers. For example, the bonding electrode BDE may be composed of multiple layers that a first electrode layer containing titanium (Ti), a second electrode layer containing gold (Au) and/or tin (Sn), and a third electrode layer containing titanium (Ti) are stacked sequentially. However, the embodiments are not limited thereto.

The first electrode ITO1 may be located on the bonding electrode BDE. The first electrode ITO1 may be provided as an anode AE of the sub-pixel circuit SPC (see FIG. 2) included in the first sub-pixel SP1 (see FIG. 4). In embodiments, the first electrode ITO1 may include at least one of transparent conductive materials, such as indium tin oxide (ITO), indium zinc oxide (IZO), zinc oxide (ZnOx), indium gallium zinc oxide (IGZO), or indium tin zinc oxide (ITZO). However, the embodiments are not limited thereto. For example, the first electrode ITO1 may include titanium nitride.

The first light-emitting element LD1 may be located on the first electrode ITO1. The first light-emitting element LD1 may be electrically connected to the first electrode ITO1. Additionally, the light-emitting element LD1 may be electrically connected to the second electrode ITO2. In embodiments, the first light-emitting element LD1 may emit orange-colored light. In this case, the first light-emitting element LD1 may emit light having a dominant wavelength of about 580 nm to about 620 nm.

The first light-emitting element LD1 may include a first semiconductor layer SCL1, a first active layer AL1, and a second semiconductor layer SCL2. The first semiconductor layer SCL1, the first active layer AL1, and the second semiconductor layer SCL2) may be sequentially stacked on the first electrode ITO1.

The first semiconductor layer SCL1 may be located on the first electrode ITO1, and may provide holes to the first active layer AL1. The first semiconductor layer SCL1 may include at least one p-type semiconductor layer. For example, the first semiconductor layer SCL1 may include at least one semiconductor material selected from gallium nitride (GaN), aluminum gallium nitride (AlGaN), indium gallium nitride (InGaN), aluminum nitride (AlN), or indium nitride (InN), and may be a p-type semiconductor layer doped with the first conductive dopant (or p-type dopant), such as magnesium (Mg), zinc (Zn), calcium (Ca), strontium (Sr), barium (Ba), etc. However, the material constituting the first semiconductor layer SCL1 is not limited thereto, and various other materials may constitute the first semiconductor layer SCL1. For example, the first semiconductor layer SCL1 may include a gallium nitride (GaN) semiconductor material doped with the first conductive dopant (or p-type dopant).

The first active layer AL1 may be located on the first semiconductor layer SCL1, and may be a region where electrons and holes recombine. As electrons and holes recombine in the first active layer AL1, the energy level transitions to a lower energy level, and light having a corresponding wavelength may be generated. The first active layer AL1 may be formed as a single or multiple quantum well structure. When the first active layer AL1 is formed in a multi-quantum well structure, units including a barrier layer, a strain-reinforcing layer, and a well layer may be repeatedly stacked to form the first active layer AL1. However, the embodiments are not limited thereto.

The second semiconductor layer SCL2 may be located on the first active layer AL1 and may provide electrons to the first active layer AL1. The second semiconductor layer SCL2 may include a different type of semiconductor layer from the first semiconductor layer SCL1. For example, the second semiconductor layer SCL2 may include at least one n-type semiconductor layer. For example, the second semiconductor layer SCL2 may include at least one semiconductor material selected from gallium nitride (GaN), aluminum gallium nitride (AlGaN), indium gallium nitride (InGaN), aluminum nitride (AlN), or indium nitride (InN), and may be an n-type semiconductor layer doped with the second conductive dopant (or n-type dopant), such as silicon (Si), germanium (Ge), tin (Sn), etc. However, the material constituting the second semiconductor layer SCL2 is not limited thereto, and various other materials may constitute the second semiconductor layer SCL2. For example, the second semiconductor layer SCL2 may include a gallium nitride (GaN) semiconductor material doped with the second conductive dopant (or n-type dopant).

An auxiliary layer may be located on the second semiconductor layer SCL2. The auxiliary layer may include a gallium nitride (GaN) semiconductor material that is not doped with impurities, and may form an n-type semiconductor layer together with the second semiconductor layer SCL).

The second electrode ITO2 may be located on the first light-emitting element LD1. For example, the second electrode ITO2 may be located on the second semiconductor layer SCL2. The second electrode ITO2 may be provided as the cathode CE of the sub-pixel circuit SPC (see FIG. 2) included in the first sub-pixel SP1 (see FIG. 4). The second electrode ITO2 may extend on the first light-emitting element LD1 to cover the side surface of the protective layer PL, and may be located on the first insulating layer IL1.

In embodiments, the second electrode ITO2 may include at least one of transparent conductive materials, such as indium tin oxide (ITO), indium zinc oxide (IZO), zinc oxide (ZnOx), indium gallium zinc oxide (IGZO), or indium tin zinc oxide (ITZO). However, the embodiments are not limited thereto. For example, the second electrode ITO2 may include titanium nitride.

The protective layer PL may cover an outer peripheral surface of the first light-emitting element LD1. The protective layer PL may reduce or prevent the likelihood of an electrical short that may otherwise occur when the first active layer AL1 contacts a conductive material other than the first semiconductor layer SCL1 and the second semiconductor layer SCL2. The protective layer PL may be composed of multiple layers. For example, the protective layer PL may include a first protective layer PL1 and a second protective layer PL2.

The first protective layer PL1 may be located on the first electrode ITO1.

The first protective layer PL1 may extend on the first electrode ITO1 to cover the side surface of the first light-emitting element LD1, and may be located on the second electrode ITO2. The first protective layer PL1 may include an insulating material. For example, the first protective layer PL1 may include at least one of zirconium dioxide (ZrO₂), aluminum oxide (Al₂O₃), or silicon dioxide (SiO₂). However, the embodiments are not limited thereto. The first protective layer PL1 may be composed of multiple layers that the above-described insulating materials stack.

The second protective layer PL2 may be located on the pixel circuit layer PCL. The second protective layer PL2 may extend on the pixel circuit layer PCL to cover both the side of the bonding electrode BDE and the side of the first electrode ITO1, and may be located on the first protective layer PL1. The second protective layer PL2 may include an insulating material. For example, the second protective layer PL2 may include at least one of metal oxides, such as silicon nitride (SiNx), silicon oxide (SiOx), silicon oxynitride (SiOxNy), or aluminum oxide (AlOx). However, the embodiments are not limited thereto.

The reflective layer RFL may be located on the pixel circuit layer PCL. The reflective layer RFL may extend on the pixel circuit layer PCL, and may be located on the side of the second protective layer PL2. The top surface of the reflective layer RFL may be located on the same line as the top surface of the second protective layer PL2. The reflective layer RFL may reflect incident light, thereby improving light output efficiency. The reflective layer RFL may include a material suitable for reflecting light. For example, the reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or an alloy of two or more materials selected therefrom. However, the embodiments are not limited thereto.

The first insulating layer IL1 may be located between the pixel circuit layer PCL and the second electrode ITO2. The first insulating layer IL1 may cover the reflective layer RFL and the second protective layer PL2. The first insulating layer IL1 may include an inorganic material or an organic material. For example, the inorganic material may include at least one of metal oxides, such as silicon oxide (SiOx), silicon nitride (SiNx), silicon oxynitride (SiOxNy), or aluminum oxide (AlOx). For example, organic materials may include at least one of acrylic resin, epoxy resin, phenolic resin, polyamide resin, polyimide resin, unsaturated polyester resin, poly-phenylene ether resin, poly-phenylene sulfide resin, or benzocyclobutene resin.

The second insulating layer IL2 may be located on the second electrode ITO2. The second insulating layer IL2 may be made of substantially the same material as the first insulating layer IL1.

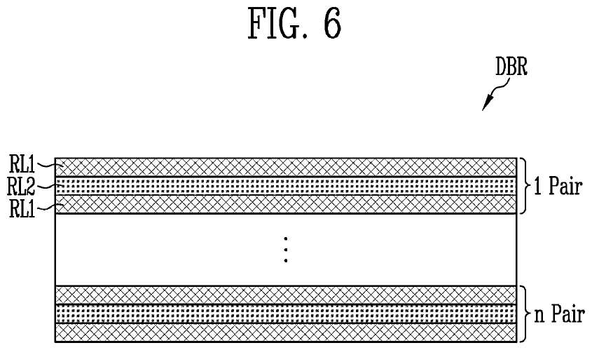

The distributed Bragg reflective layer DBR may be located on the second insulating layer IL2. The distributed Bragg reflective layer DBR may be spaced apart from the second electrode ITO2. The distributed Bragg reflective layer DBR may function as a reflection filter. The distributed Bragg reflective layer DBR may selectively reflect (or transmit) incident light. For example, the distributed Bragg reflective layer DBR may reflect short-wavelength light, and may transmit long-wavelength light among the orange-colored light emitted from the first light-emitting element LD1. The long-wavelength light may mean light close to a red color, and the short-wavelength light may mean light close to an orange color. Because the short-wavelength light reflected from the distributed Bragg reflective layer DBR is reabsorbed and recycled in the first active layer AL1, light efficiency may increase. In addition, because the short-wavelength light is filtered in the distributed Bragg reflective layer DBR and the long-wavelength light close to a red color is emitted, color purity may increase. The structure of the distributed Bragg reflective layer DBR will be described in greater detail later with reference to FIG. 6.

Light emitted from the first light-emitting element LD1 may be incident on the distributed Bragg reflective layer DBR in all directions. The performance of the distributed Bragg reflective layer DBR may vary depending on the incident angle (θ) (or direction) of incident light. For example, as the incident angle (θ) of the short-wavelength light incident on the distributed Bragg reflective layer DBR decreases, the reflectance of the short-wavelength light may increase. For example, as the angle of incidence (θ) of the short-wavelength light incident on the distributed Bragg reflective layer DBR increases, the reflectance of the short-wavelength light may decrease. As the incident angle (θ) of light incident on the distributed Bragg reflective layer DBR increases, the amount of shift in the wavelength of light reflected from the distributed Bragg reflective layer DBR increases, thereby deteriorating the function of the distributed Bragg reflective layer DBR.

The color filter CF may be located on the distributed Bragg reflective layer DBR. For example, the color filter CF may be located directly on the distributed Bragg reflective layer DBR. The color filter CF may overlap the first light-emitting element LD. For example, the color filter CF may overlap the first emission area EMA1 on the distributed Bragg reflective layer DBR. The color filter CF may partially overlap the non-emissive area NEA.

In one or more embodiments, the color filter CF may selectively transmit red color light. For example, the color filter CF may function as an absorption filter that absorbs light of colors other than red color. For example, the color filter CF may function as a reflection filter that reflects light of colors other than red color. As the angle of incidence (θ) of the short-wavelength light incident on the distributed Bragg reflective layer DBR increases, not only the long-wavelength light close to red color, but also the short-wavelength light close to orange color may transmit through the distributed Bragg reflective layer DBR. The color filter CF may absorb or reflect the short-wavelength light close to the orange color that is not filtered in the distributed Bragg reflective layer DBR. The color filter CF may further increase color purity by transmitting the long-wavelength light close to red color, and filtering the short-wavelength light close to orange color.

The lens LA may be located on the distributed Bragg reflective layer DBR. For example, the lens LA may be located between the distributed Bragg reflective layer DBR and the color filter CF. The lens LA may overlap the first light-emitting element LD. For example, the lens LA may overlap the first emission area EMA1 on the distributed Bragg reflective layer DBR. The lens LA may partially overlap the non-emissive area NEA. The lens LA may improve light output efficiency by outputting the light emitted from the first light-emitting element LD1 through an intended path. The lens may be a micro lens, but embodiments are not limited thereto.

FIG. 6 is a cross-sectional view of a distributed Bragg reflective layer according to some embodiments.

Referring to FIG. 6, the distributed Bragg reflective layer DBR may have a structure suitable for transmitting the long-wavelength light close to red color. The distributed Bragg reflective layer DBR may include a first refractive layer RL1 and a second refractive layer RL2 having different refractive indices. For example, the refractive index of the first refractive layer RL1 may be higher than the refractive index of the second refractive layer RL2. The distributed Bragg reflective layer DBR may include at least one multilayer in which the first refractive layer RL1, the second refractive layer RL2, and the first refractive layer RL1 are sequentially stacked. The distributed Bragg reflective layer DBR may have a structure in which n multiple layers (1 Pair to n Pair) are stacked. For example, the distributed Bragg reflective layer DBR may include 3 to 60 multilayers (n=3 to 60).

In one or more embodiments, the first refractive layer RL1 may include titanium dioxide (TiO₂), and the second refractive layer RL2 may include silicon dioxide (SiO₂). In this case, the multilayer has a TiO2/SiO₂/TiO2 stacked structure, and the thickness of the multilayer may be about 130 nm to about 160 nm. In one or more embodiments, the first refractive layer RL1 may include tantalum dioxide (TaO₂), and the second refractive layer RL2 may include silicon dioxide (SiO₂). In this case, the multilayer has a TaO₂/SiO₂/TaO₂ stacked structure, and the thickness of the multilayer may be about 150 nm to about 180 nm.

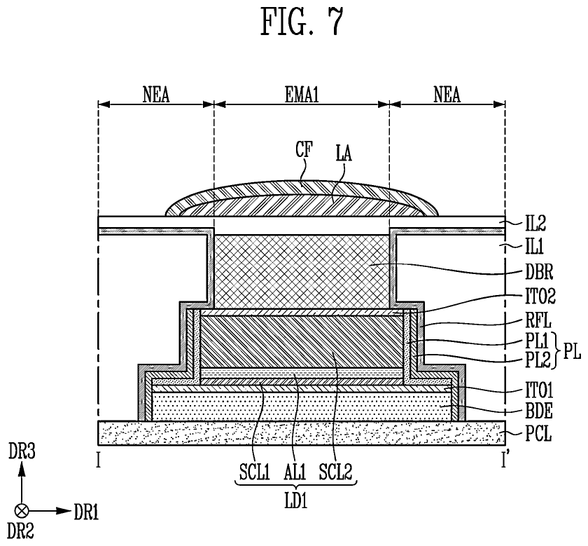

FIG. 7 is a cross-sectional view taken along the line I-I′ of FIG. 4 according to some embodiments. With regard to FIG. 7, descriptions of content overlapping FIG. 5 will be simplified or omitted.

Referring to FIG. 7, the second electrode ITO2 may be located on the second semiconductor layer SCL2 of the first light-emitting element LD1. The second electrode ITO2 may entirely overlap the first light-emitting element LD1.

The distributed Bragg reflective layer DBR may be located on the second electrode ITO2. For example, the distributed Bragg reflective layer DBR may be located directly on the second electrode ITO2. The distributed Bragg reflective layer DBR may partially overlap the first light-emitting element LD1.

The first protective layer PL1 may be located on the first electrode ITO1. The first protective layer PL1 may extend on the first electrode ITO1, and may cover the side surface of the first light-emitting element LD1 and the side surface of the second electrode ITO2. The top surface of the first protective layer PL1 may be located on the same line as the top surface of the second electrode ITO2.

The second protective layer PL2 may be located on the pixel circuit layer PCL. The second protective layer PL2 may extend on the pixel circuit layer PCL, and may cover the side surface of the bonding electrode BDE, the side surface of the first electrode ITO1, and the side surface of the first protective layer PL1. The top surface of the second protective layer PL2 may be located on the same line as (e.g., may be level with) the top surface of the first protective layer PL1.

The reflective layer RFL may be located on the pixel circuit layer PCL. The reflective layer RFL may extend on the pixel circuit layer PCL, may be located on the first protective layer PL1 and the second protective layer PL2, and may be partially located on the second electrode ITO2. Additionally, the reflective layer RFL may extend on the second electrode ITO2, and may cover the side surface of the distributed Bragg reflective layer DBR.

The first insulating layer IL1 may be located between the pixel circuit layer PCL and the reflective layer RFL. The first insulating layer IL1 may cover the reflective layer RFL. The second insulating layer IL2 may be located on the distributed Bragg reflective layer DBR and the reflective layer RFL.

The color filter CF may be located on the second insulating layer IL2. The color filter CF may be spaced apart from the distributed Bragg reflective layer DBR. The lens LA may be located on the second insulating layer IL2. For example, the lens LA may be located between the second insulating layer IL2 and the color filter CF.

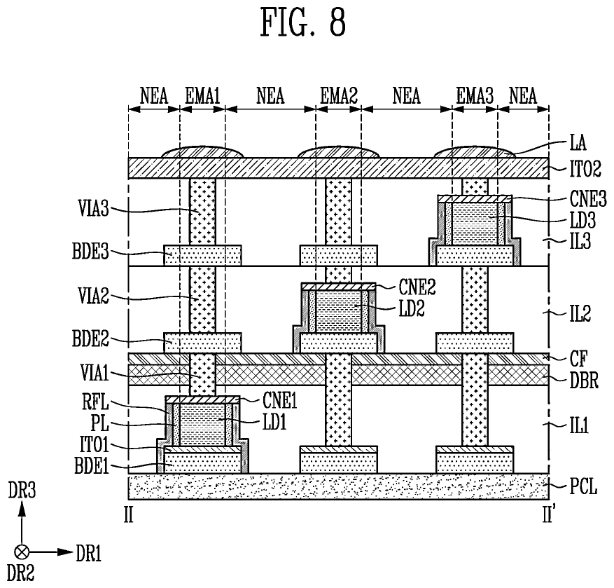

FIG. 8 is a cross-sectional view taken along the line II-II′ of FIG. 4 according to some embodiments. Descriptions of content overlapping the content described above in relation to FIG. 8 will be simplified or omitted.

Referring to FIG. 8, first bonding electrodes BDE1 may be located on the pixel circuit layer PCL. The first bonding electrodes BDE1 may be spaced apart from each other. Each of the first bonding electrodes BDE1 may overlap the first to third light-emitting areas EMA1, EMA2, and EMA3.

First electrodes ITO1 may be located on the first bonding electrodes BDE1. The first electrode ITO1 overlapping the first light-emitting area EMA1 may serve as the anode AE of the sub-pixel circuit SPC (see FIG. 2) included in the first sub-pixel SP1 (see FIG. 4). The first electrode ITO1 overlapping the second emission area EMA2 may serve as the anode AE of the sub-pixel circuit SPC included in the second sub-pixel SP2 (see FIG. 4). The first electrode ITO1 overlapping the third emission area EMA3 may serve as the anode AE of the sub-pixel circuit SPC included in the third sub-pixel SP3 (see FIG. 4). The first electrode ITO1 overlapping the first light-emitting area EMA1 may be electrically connected to the first light-emitting element LD1. The first electrode ITO1 overlapping the second light-emitting area EMA2 may be electrically connected to the second light-emitting element LD2 through the first via VIA overlapping the second light-emitting area EMA2. The first electrode ITO1 overlapping the third light-emitting area EMA3 may be electrically connected to the third light-emitting element LD3 through the first and second vias VIA1 and VIA2 overlapping the third light-emitting area EMA3.

The first light-emitting element LD1 may be located on the first electrode ITO1 overlapping the first light-emitting area EMA1. The first light-emitting element LD1 may emit orange-colored light. The first light-emitting element LD1 may include a first semiconductor layer SCL1 (see FIG. 5), a first active layer AL1 (see FIG. 5), and a second semiconductor layer SCL2 (see FIG. 5) that are sequentially stacked between the first electrode ITO1 and the first connection electrode CNE1.

The protective layer PL may be located on the first electrode ITO1. The protective layer PL may extend on the first electrode ITO1, and may cover the side surface of the first light-emitting element LD1.

The reflective layer RFL may be located on the pixel circuit layer PCL. The reflective layer RFL may extend on the pixel circuit layer PCL, and may be located on the first bonding electrode BDE1, the first electrode ITO1, and the protective layer PL.

A first connection electrode CNE1 may be located on the first light-emitting element LD1. The first connection electrode CNE1 may be located on the protective layer PL and the reflective layer RFL.

The first insulating layer IL1 may be located on the pixel circuit layer PCL. The first insulating layer IL1 may be located on the same layer as the first light-emitting element LD1.

The distributed Bragg reflective layer DBR may be located on the first insulating layer IL1. For example, the distributed Bragg reflective layer DBR may be entirely located on (e.g., may cover an entirety of, or may cover almost an entirety of) the first insulating layer IL1. As described above, the distributed Bragg reflective layer DBR may reflect short-wavelength light, and may transmit long-wavelength light emitted from the first light-emitting element LD1.

The color filter CF may be located on the distributed Bragg reflective layer DBR. For example, the color filter CF may be located entirely on the distributed Bragg reflective layer DBR. The color filter CF may transmit red color light, and may reflect or absorb light other than red color. Accordingly, the color filter CF may be located above the first light-emitting element LD1, and below the second light-emitting element LD2 and the third light-emitting element LD3. As described above, the color filter CF may be incident on the distributed Bragg reflective layer DBR at a relatively large incident angle (θ) (see FIG. 5) and may filter unfiltered short-wavelength light, and may transmit long-wavelength light to improve color purity.

First vias VIA1 penetrating the first insulating layer IL1, the distributed Bragg reflective layer DBR, and the color filter CF may be provided. The first via VIA1 overlapping the first emission area EMA1 may be formed on the first connection electrode CNE1 to electrically connect the first connection electrode CNE1 and the second bonding electrode BDE2. The first via VIA1 overlapping the second light-emitting area EMA2 may be formed on the first electrode ITO1 to electrically connect the first electrode ITO1 and the second bonding electrode BDE2. The first via VIA1 overlapping the third light-emitting area EMA3 may be formed on the first electrode ITO1 to electrically connect the first electrode ITO1 and the second bonding electrode BDE2.

Second bonding electrodes BDE2 may be located on the color filter CF. The second bonding electrodes BDE2 may be spaced apart from each other. Each of the second bonding electrodes BDE2 may overlap the first to third light-emitting areas EMA1, EMA2, and EMA3.

The second light-emitting element LD2 may be located on the second bonding electrode BDE2 overlapping the second light-emitting area EMA2. The second light-emitting element LD2 may emit green-colored light. The second light-emitting element LD2 may include a first semiconductor layer SCL1 (see FIG. 5), a second active layer, and a second semiconductor layer SCL2 (see FIG. 5) that are sequentially stacked between the second bonding electrode BDE2 and the second connection electrode CNE2. The second active layer may generate green-colored light, unlike the first active layer AL1 (see FIG. 5), which generates orange-colored light.

A protective layer PL may be located on the second bonding electrode BDE2. The protective layer PL may extend on the second bonding electrode BDE2, and may cover the side surface of the second light-emitting element LD2.

A reflective layer RFL may be located on the color filter CF. The reflective layer RFL may extend on the color filter CF, and may be located on the second bonding electrode BDE2 and the protective layer PL.

A second connection electrode CNE2 may be located on the second light-emitting element LD2. The second connection electrode CNE2 may be located on the protective layer PL and the reflective layer RFL.

A second insulating layer IL2 may be located on the color filter CF. The second insulating layer IL2 may be located on the same layer as the second light-emitting element LD2.

Second vias VIA2 penetrating the second insulating layer IL2 may be provided. The second via VIA2 overlapping the first light-emitting area EMA1 may be formed on the second bonding electrode BDE2 to electrically connect the second bonding electrode BDE2 and the third bonding electrode BDE3. The second via VIA2 overlapping the second light-emitting area EMA2 may be formed on the second connection electrode CNE2 to electrically connect the second connection electrode CNE2 and the third bonding electrode BDE3. The second via VIA2 overlapping the third light-emitting area EMA3 may be formed on the second bonding electrode BDE2 to electrically connect the second bonding electrode BDE2 and the third bonding electrode BDE3.

Third bonding electrodes BDE3 may be located on the second insulating layer IL2. The third bonding electrodes BDE3 may be spaced apart from each other. Each of the third bonding electrodes BDE3 may overlap the first to third light-emitting areas EMA1, EMA2, and EMA3.

The third light-emitting element LD3 may be located on the third bonding electrode BDE3 overlapping the third light-emitting area EMA3. The third light-emitting element LD3 may emit blue-colored light. The third light-emitting element LD3 may include a first semiconductor layer SCL1 (see FIG. 5), a third active layer, and a second semiconductor layer SCL2 (see FIG. 5) that are sequentially stacked between the third bonding electrode BDE3 and the third connection electrode CNE3. The third active layer may generate blue-colored light, unlike the first active layer AL1 (see FIG. 5), which generates orange-colored light.

A protective layer PL may be located on the third bonding electrode BDE3. The protective layer PL may extend on the third bonding electrode BDE3, and may cover the side surface of the third light-emitting element LD3.

A reflective layer RFL may be located on the second insulating layer IL2. The reflective layer RFL may extend on the second insulating layer IL2, and may be located on the third bonding electrode BDE3 and the protective layer PL.

A third connection electrode CNE3 may be located on the third light-emitting element LD3. The third connection electrode CNE3 may be located on the protective layer PL and the reflective layer RFL.

A third insulating layer IL3 may be located on the second insulating layer IL2. The third insulating layer IL3 may be located on the same layer as the third light-emitting element LD3.

Third vias VIA3 penetrating the third insulating layer IL3 may be provided. The third via VIA3 overlapping the first light-emitting area EMA1 may be formed on the third bonding electrode BDE3 to electrically connect the third bonding electrode BDE3 and the second electrode ITO2. The third via VIA3 overlapping the second light-emitting area EMA2 may be formed on the third bonding electrode BDE3 to electrically connect the third bonding electrode BDE3 and the second electrode ITO2. The third via VIA3 overlapping the third light-emitting area EMA3 may be formed on the third connection electrode CNE3 to electrically connect the third connection electrode CNE3 and the second electrode ITO2.

The second electrode ITO2 may be located on the third insulating layer IL3. The second electrode ITO2 may be electrically connected to the first to third light-emitting elements LD1, LD2, and LD3. For example, the second electrode ITO2 may be electrically connected to the first light-emitting element LD1 through the first connection electrode CNE1 and the first to third vias VIA1, VIA2, and VIA3 overlapping the first light-emitting area EMA1. For example, the second electrode ITO2 may be electrically connected to the second light-emitting element LD2 through the second connection electrode CNE2 and the second and third vias VIA2 and VIA3 overlapping and the second light-emitting area EMA2. For example, the second electrode ITO2 may be electrically connected to the third light-emitting element LD3 through the third connection electrode CNE3 and the third via VIA3 overlapping the third light-emitting area EMA3.

The lenses LA may be located on the second electrode ITO2. The lenses LA may respectively overlap the first to third light-emitting areas EMA1, EMA2, and EMA3. The lenses LA may partially overlap the non-emission area NEA.

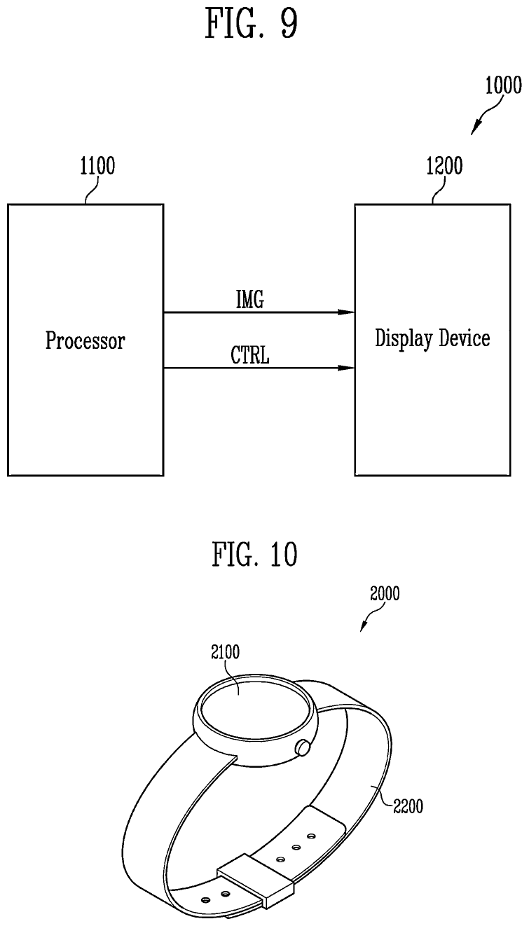

FIG. 9 is a block diagram of a display system according to some embodiments.

Referring to FIG. 9, the display system 1000 may include a processor 1100 and a display device 1200.

The processor 1100 may perform various tasks and calculations. In embodiments, the processor 1100 may include an application processor, a graphics processor, a microprocessor, a central processing unit (CPU), etc. The processor 1100 may be connected to and control other components of the display system 1000 through a bus system.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. In this case, the image data IMG and the control signal CTRL may be provided as the input image data IMG and control signal CTR of FIG. 1, respectively.

The display system 1000 may include a computing system that provides video display functions, such as a smart watch, a mobile phone, a smart phone, a portable computer, a tablet personal computer, a watch phone, an automotive display, smart glasses, a portable multimedia player (PMP), a navigation, and an ultra-mobile personal computer (UMPC). In addition, the display system 1000 may include at least one of a head mounted display (HMD) device, a virtual reality (VR) device, a mixed reality (MR) device, an augmented reality (AR) device, or the like.

FIGS. 10 to 13 are perspective views of application examples of a display system of FIG. 9.

Referring to FIG. 10, the display system 1000 of FIG. 9 may be applied to a smart watch 2000 including a display unit 2100 and a strap unit 2200.

The smart watch 2000 may be a wearable electronic device. For example, the smart watch 2000 may have a structure in which the strap unit 2200 is mounted on the user's wrist. Here, the display system 1000 and/or the display device 1200 may be applied to the display unit 2100, and image data including time information may be provided to the user.

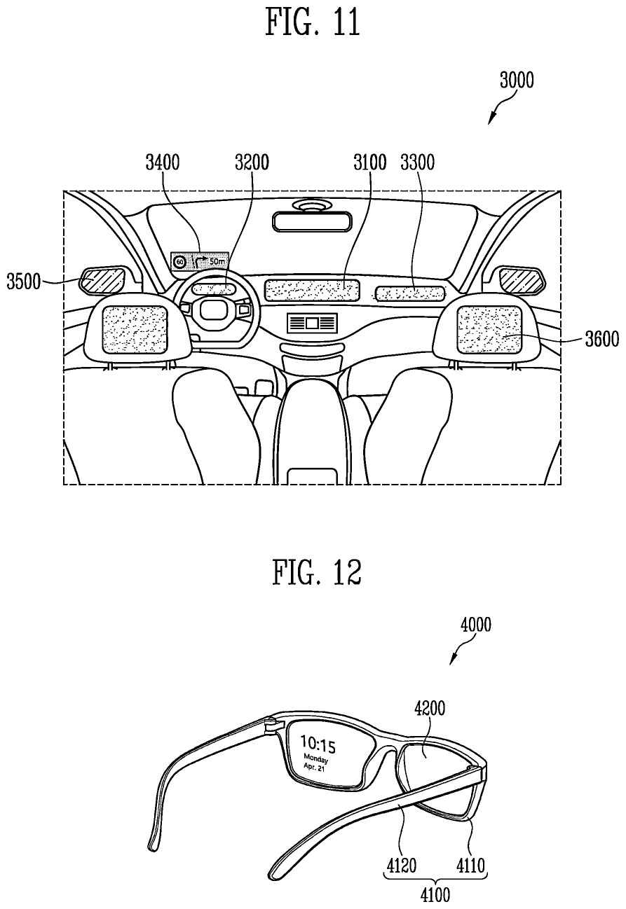

Referring to FIG. 11, the display system 1000 of FIG. 9 may be applied to an automotive display system 3000. Here, the automotive display system 3000 may include a computing system provided inside and/or outside the vehicle to provide image data.

For example, the display system 1000 and/or the display device 1200 may be applied to at least one of an infotainment panel 3100, a cluster 3200, a co-driver display 3300, a head-up display 3400, a side mirror display 3500, or a rear-seat display 3600, provided in the vehicle.

Referring to FIG. 12, the display system 1000 of FIG. 9 may be applied to smart glasses 4000. The smart glasses 4000 may be a wearable electronic device that can be worn on the user's head. For example, the smart glasses 4000 may be a wearable device for augmented reality.

The smart glasses 4000 may include a frame 4100 and a lens unit 4200. The frame 4100 may include a housing 4110 supporting the lens unit 4200 and a leg part 4120 for the user to wear. The leg part 4120 may be connected to the housing 4110 through a hinge, and may be folded or unfolded relative to the housing 4110.

A battery, a touch pad, a microphone, a camera, and the like may be embedded in the frame 4100. Additionally, a projector for outputting light, a processor for controlling light signals, and the like may be embedded in the frame 4100.

The lens unit 4200 may include an optical member that transmits or reflects light. For example, the lens unit 4200 may include glass, transparent synthetic resin, or the like.

For the user's eyes to recognize visual information, the lens unit 4200 may reflect an image by the light signal transmitted from the projector of the frame 4100 by using a back surface (e.g., surface facing the user's eyes) of the lens unit 4200. For example, the user may recognize visual information, such as time and date displayed on the lens unit 4200. At this time, the projector and/or lens unit 4200 may be a type of display device. The display device 1200 may be applied to the projector and/or the lens unit 4200.

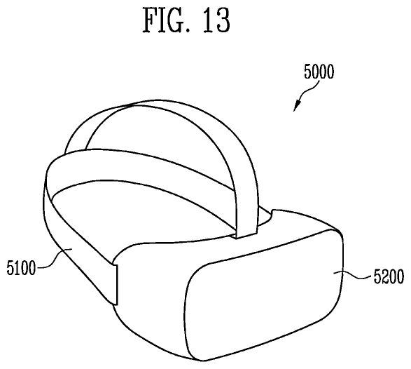

Referring to FIG. 13, the display system 1000 of FIG. 9 may be applied to a head mounted display device 500.

The head mounted display device 5000 may be a wearable electronic device that can be worn on the user's head. For example, the head mounted display device 5000 may be a wearable device for virtual reality or mixed reality.

The head mounted display device 5000 may include a head mounting band 5100 and a display device storage case 5200. The head mounting band 5100 may be connected to the display device storage case 5200. The head mounting band 5100 may include a horizontal band and/or a vertical band for fixing the head mounted display device 5000 to the user's head. The horizontal band may be configured to surround the sides of the user's head, and the vertical band may be configured to surround the top of the user's head. However, the embodiments are not limited thereto. For example, the head mounting band 5100 may be implemented in the form of a glasses frame, a helmet, etc.

The display device storage case 5200 may accommodate the display system 1000 and/or the display device 1200.

However, aspects of the present disclosure are not limited to those described above, and various other aspects would be understood by one of ordinary skill in the art within the spirit and scope of the present disclosure.

The embodiments described in detail above are provided to explain the present disclosure, but these embodiments are not intended to limit the scope of the present disclosure. It should be understood by those skilled in the art that various changes, substitutions, and alternations may be made therein without departing from the scope of the disclosure as defined by the following claims and their equivalents.

The scope of embodiments according to the present disclosure is not limited by detailed descriptions of the present specification and should be defined by the accompanying claims and their equivalents. Furthermore, all changes or modifications of the present disclosure derived from the claims, and equivalents thereof, should be construed as being included in the scope of embodiments according to the present disclosure. The embodiments may be combined to form additional embodiments.

What is claimed is:

1. A display device, comprising:
a pixel circuit layer;
a bonding electrode above the pixel circuit layer;
a first electrode above the bonding electrode;
a light-emitting element above the first electrode for emitting light of a first color;
a second electrode above the light-emitting element;
a distributed Bragg reflective layer above the second electrode; and
a color filter above the distributed Bragg reflective layer for transmitting light of a second color.

2. The display device according to claim 1, wherein the first color is orange.

3. The display device according to claim 1, wherein the second color is red.

4. The display device according to claim 3, wherein the color filter is configured to absorb or reflect light of a color other than red.

5. The display device according to claim 1, further comprising a lens between the distributed Bragg reflective layer and the color filter.

6. The display device according to claim 1, further comprising:
a first protective layer on the first electrode, on a side surface of the light-emitting element, and on the second electrode;
a second protective layer on the pixel circuit layer, on the bonding electrode, on the first electrode, and on the first protective layer; and
a reflective layer on a side surface of the second protective layer and on the pixel circuit layer.

7. The display device according to claim 6, wherein the reflective layer does not overlap the light-emitting element.

8. The display device according to claim 6, further comprising:
a first insulating layer between the pixel circuit layer and the second electrode, and covering the reflective layer and the second protective layer; and
a second insulating layer on the second electrode and the distributed Bragg reflective layer.

9. The display device according to claim 1, wherein the distributed Bragg reflective layer comprises at least one multilayer in which a first refractive layer, a second refractive layer, and another first refractive layer are sequentially stacked.

10. The display device according to claim 9, wherein the first refractive layers comprise titanium dioxide,
wherein the second refractive layer comprises silicon dioxide, and
wherein a thickness of the multilayer is about 130 nm to about 160 nm.

11. The display device according to claim 9, wherein the first refractive layers comprise tantalum dioxide,
wherein the second refractive layer comprises silicon dioxide, and
wherein a thickness of the multilayer is about 150 nm to about 180 nm.

12. The display device according to claim 9, wherein the multilayer comprises 3 to 60 layers.

13. The display device according to claim 1, further comprising:
a first protective layer on the first electrode, on a side surface of the light-emitting element, and on a side surface of the second electrode;
a second protective layer on a side surface of the first protective layer, on the pixel circuit layer, on the bonding electrode, and on the first electrode; and
a reflective layer on a side surface of the distributed Bragg reflective layer, on the pixel circuit layer, on the first protective layer, on the second protective layer, and on the second electrode.

14. The display device according to claim 13, wherein the reflective layer partially overlaps the light-emitting element.

15. The display device according to claim 13, further comprising:
a first insulating layer between the reflective layer and the pixel circuit layer; and
a second insulating layer between the color filter and the distributed Bragg reflective layer and the reflective layer.

16. A display device comprising:
a first light-emitting element at a same layer as a first insulating layer above a pixel circuit layer, and configured to emit light of a first color;
a distributed Bragg reflective layer above the first insulating layer;
a color filter above the distributed Bragg reflective layer, and configured to transmit red color light;
a second light-emitting element at same layer as a second insulating layer above the color filter, and configured to emit light of a second color; and
a third light-emitting element at same layer as a third insulating layer above the second insulating layer, and configured to emit light of a third color.

17. The display device according to claim 16, wherein the first color is orange, wherein the second color is green, and wherein the third color is blue.

18. The display device according to claim 16, further comprising:
first electrodes above the pixel circuit layer;
first vias penetrating the first insulating layer, the distributed Bragg reflective layer, and the color filter;
second vias penetrating the second insulating layer;
third vias penetrating the third insulating layer;
a second electrode above the third insulating layer; and
lenses above the second electrode, and respectively overlapping the first light-emitting element, the second light-emitting element, and the third light-emitting element.

19. The display device according to claim 18, wherein the first light-emitting element is above one of the first electrodes overlapping a first light-emitting area, and is electrically connected to the second electrode through one of the first vias overlapping the first light-emitting area, one of the second vias overlapping the first light-emitting area, and one of the third vias overlapping the first light-emitting area.

20. The display device according to claim 18, wherein the second light-emitting element is electrically connected to one of the first electrodes overlapping a second light-emitting area through one of the first vias overlapping the second light-emitting area, and is electrically connected to the second electrode through one of the second vias overlapping the second light-emitting area and one of the third vias overlapping the second light-emitting area.

21. The display device of claim 18, wherein the third light-emitting element is electrically connected to one of the first electrodes overlapping a third light-emitting area through one of the first vias overlapping the third light-emitting area and one of the second vias overlapping the third light-emitting area, and is electrically connected to the second electrode through one of the third vias overlapping the third light-emitting area.
